(19) United States
(12) Patent Application Publication
(10) Pub. No.: US 2024/0021491 A1
(43) Pub. Date: Jan. 18, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Chen-Hsuan Tsai, Taitung City (TW); Tsung-Fu Tsai, Changhua County (TW); Hung-Chih Chen, Hsinchu City (TW); Chin-Chuan Chang, Hsinchu County (TW)

(73) Assignee: Taiwan Semiconductor Manufacturing Company, Ltd., Hsinchu (TW)

(21) Appl. No.: 17/866,532

(22) Filed: Jul. 17, 2022

(51) Int. Cl. H01L 23/367; H01L 23/00; H01L 23/373; H01L 21/56; H01L 21/48; H01L 25/065

(52) U.S. Cl. CPC H01L 23/3675; H01L 24/32; H01L 23/3733; H01L 21/565; H01L 21/563; H01L 21/4882; H01L 25/0652; H01L 2224/32225; H01L 2224/73204; H01L 2224/16227; H01L 24/16; H01L 24/73; H01L 2924/182; H01L 2924/15331; H01L 2224/16238; H01L 2924/37001

(57) ABSTRACT

A semiconductor device includes a first integrated circuit die and a second integrated circuit die. The first integrated circuit die includes a conductive paste on a first surface of the first integrated circuit die, wherein the conductive paste is in direct contact with the first surface of the first integrated circuit die. The second integrated circuit die is disposed aside the first integrated circuit die, wherein a surface of the conductive paste is substantially coplanar with a surface of the second integrated circuit die.

### BACKGROUND

The semiconductor industry has experienced rapid growth due to continuous improvements in the integration density of various electronic components (e.g., transistors, diodes, resistors, capacitors, etc.). For the most part, this improvement in integration density has come from repeated reductions in minimum feature size, which allows more of the smaller components to be integrated into a given area. These smaller electronic components may require smaller packages that utilize less area than previous packages. Currently, integrated fan-out packages are becoming increasingly popular for their compactness. How to ensure the reliability of the integrated fan-out packages has become a challenge in the field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are schematic cross-sectional views of various stages in a method of forming a semiconductor device according to some embodiments.

FIG. 2 illustrates a top view of a semiconductor device of FIG. 1E in accordance with some embodiments of the disclosure.

FIG. 3A to FIG. 3F are schematic cross-sectional views of various stages in a method of forming a semiconductor device according to some embodiments.

FIG. 4A to FIG. 4D are schematic cross-sectional views of various stages in a method of forming a semiconductor device according to some embodiments.

FIG. 5A to FIG. 5E respectively illustrate a top view of a semiconductor device of FIG. 4D in accordance with some embodiments of the disclosure.

FIG. 6 illustrates a schematic cross-sectional view of a semiconductor device according to some embodiments.

FIG. 7 illustrates a schematic cross-sectional view of a semiconductor device according to some embodiments.

FIG. 8 illustrates a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

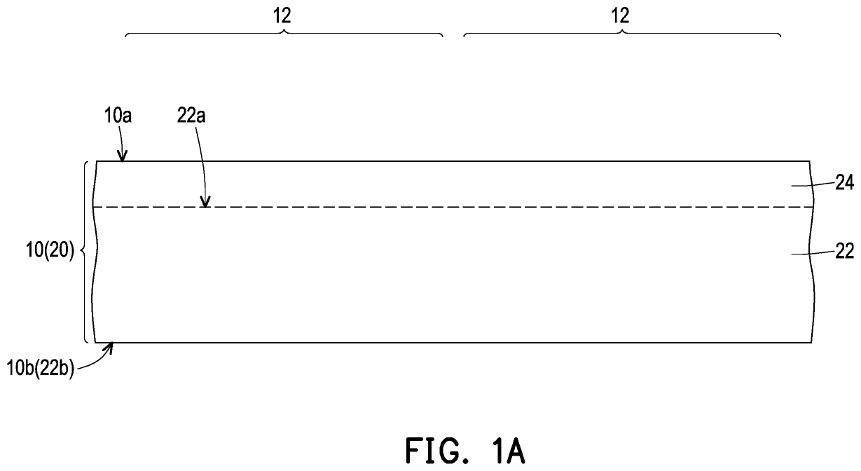

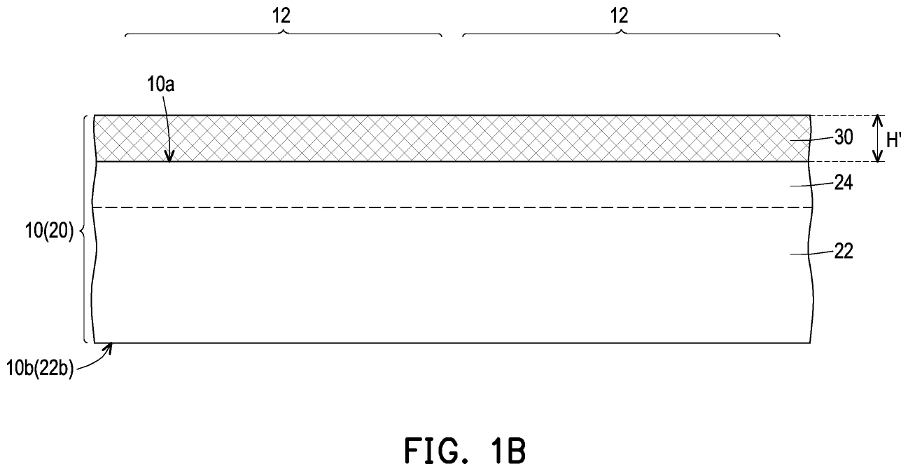

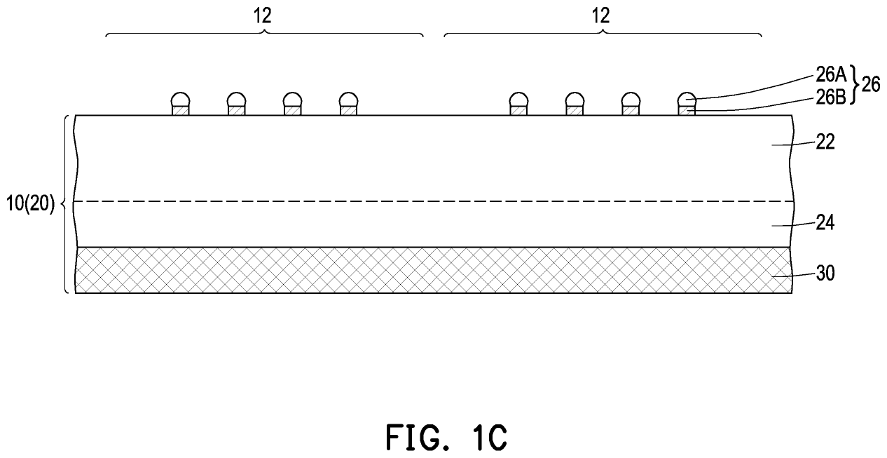

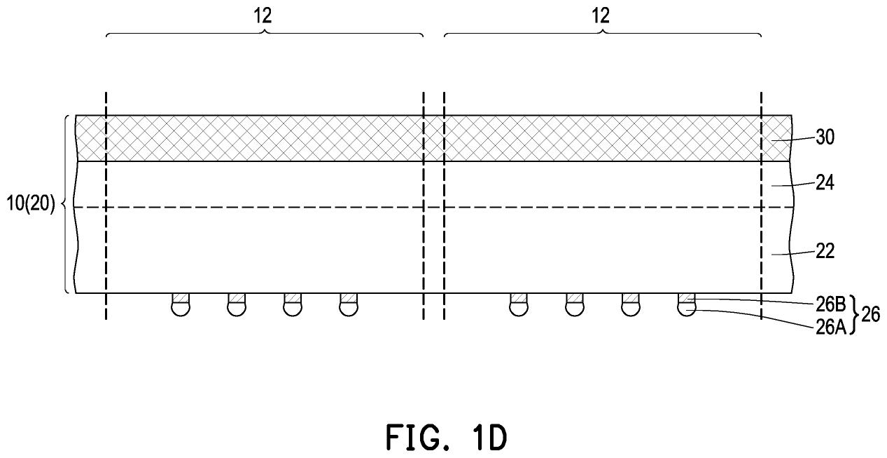

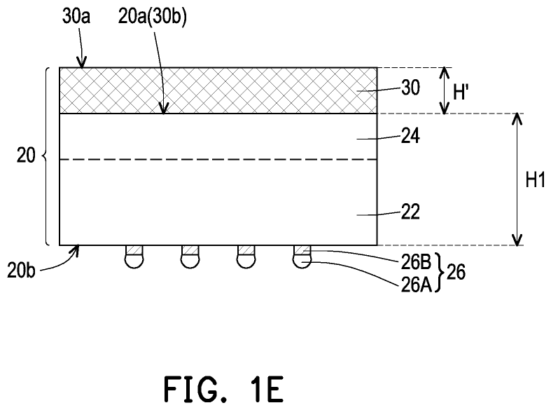

FIG. 1A to FIG. 1E are schematic cross-sectional views of various stages in a method of forming a semiconductor device according to some embodiments.

Referring to FIG. 1A, a wafer 10 is provided. The wafer 10 has a first surface 10a (e.g., a front-side) and a second surface 10b (e.g., a backside) opposite to the first surface 10a. The wafer 10 may include a plurality of die regions 12 that are singulated in subsequent steps to form a plurality of integrated circuit dies 20. For example, the die regions 12 are separated by scribe line regions (not shown) therebetween. In some embodiments, the integrated circuit dies 20 have the same size (e.g., same height and/or surface area). In alternative embodiments, the integrated circuit dies 20 have different sizes (e.g., different heights and/or surface areas). Each integrated circuit die 20 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit die 20 will be packaged in subsequent processing to form a semiconductor device such as a semiconductor package.

The integrated circuit die 20 may include a semiconductor substrate 22 and an interconnect structure 24. The semiconductor substrate 22 may be a substrate of silicon, doped or undoped, or an active layer of a semiconductor-on-insulator (SOI) substrate. The semiconductor substrate 22 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 22 has a first surface 22a (e.g., an active or a front-side surface) and a second surface 22b (e.g., an inactive or a backside surface).

Devices (not shown) may be formed at the first surface 22a of the semiconductor substrate 22. The devices may be active devices (e.g., transistors, diodes, etc.), capacitors, resistors, the like, or combinations thereof. An inter-layer dielectric (ILD) (not separately illustrated) is over the first surface 22a of the semiconductor substrate 22. The ILD surrounds and may cover the devices. The ILD may include one or more dielectric layers formed of materials such as phospho-silicate glass (PSG), boro-silicate glass (BSG), boron-doped phospho-silicate glass (BPSG), undoped silicate glass (USG), or the like.

Conductive plugs (not separately illustrated) may extend through the ILD to electrically and physically couple the devices. For example, when the devices are transistors, the conductive plugs couple the gates and source and drain regions of the transistors. The conductive plugs may be formed of tungsten, cobalt, nickel, copper, silver, gold, aluminum, the like, or combinations thereof.

The interconnect structure 24 is over the first surface 22a of the semiconductor substrate 22, and is used to electrically connect the devices of the semiconductor substrate 22 to form an integrated circuit. The interconnect structure 24 may be over the ILD and the conductive plugs. The interconnect structure 24 may include one or more dielectric layer(s) and respective metallization layer(s) in the dielectric layer(s). Acceptable dielectric materials for the dielectric layers include low-k dielectric materials such as PSG, BSG, BPSG, USG, or the like. Acceptable dielectric materials for the dielectric layers further include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers may include conductive vias and/or conductive lines to interconnect the devices of the semiconductor substrate 22. The metallization layers may be formed of a conductive material, such as a metal, such as copper, cobalt, aluminum, gold, combinations thereof, or the like. The interconnect structure 24 may be formed by a damascene process, such as a single damascene process, a dual damascene process, or the like.

Referring to FIG. 1B, a conductive paste 30 is formed on the first surface 10a of the wafer 10. In some embodiments, the conductive paste 30 is formed on the first surface 10a of the wafer 10 by a printing process, a dispensing process, a lamination process, the like, combinations thereof, or any other suitable process. The printing process includes a stencil printing, a screen printing, the like, or combinations thereof. In an embodiment in which the stencil printing or screen printing is performed, the wafer 10 is placed in a stencil-holder or a screen-holder. The thickness of the holder may be substantially equal to a thickness of the wafer plus a thickens of the conductive paste 30. After the placement, the first surface 10a of the wafer 10 is exposed and upward. The first surface 10a of the wafer 10 is the outermost surface of the wafer 10, for example. Then, the conductive paste 30 may be printed on the first surface 10a of the wafer 10. In an embodiment in which the dispensing process is performed, the conductive paste 30 is directly dispensing onto the first surface 10a of the wafer 10 with a dispensing device. In an embodiment in which the lamination process is performed, the conductive paste 30 is in a form of film and has a profile and an area similar to that of the first surface 10a of the wafer 10, and the film-type conductive paste 30 is placed and then pressed onto the first surface 10a of the wafer 10. In some embodiments, after the conductive paste 30 is formed, a sintering process is performed on the conductive paste 30, at a sintering temperature of about 180° C. to about 250° C. for about 30 minutes to 240 minutes. In some embodiments, the conductive paste 30 is also referred to as a heat dissipation pattern, a heat dissipation layer or a conductive layer.

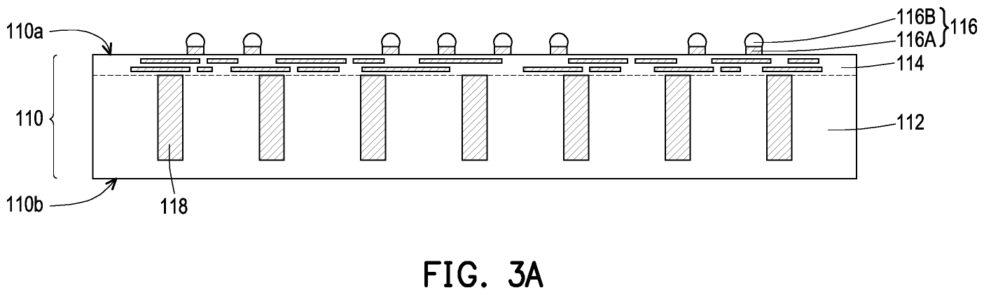

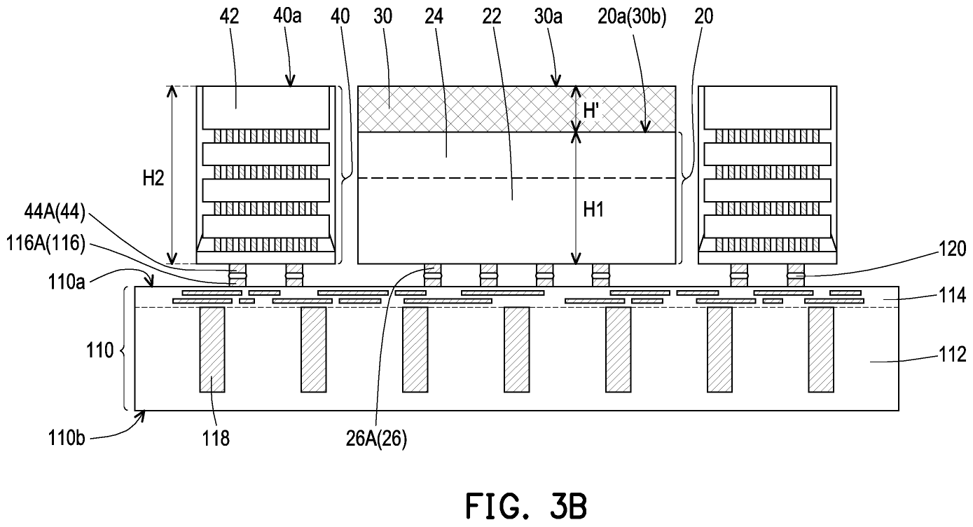

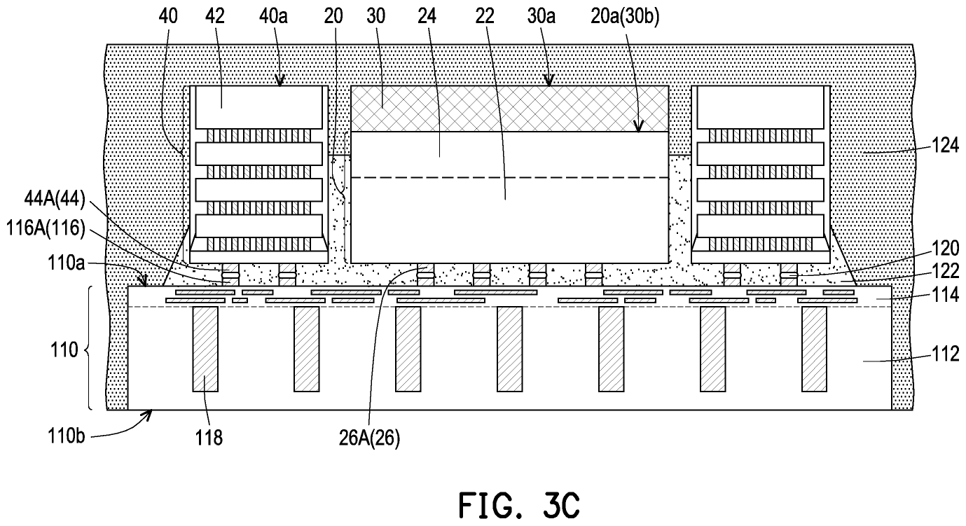

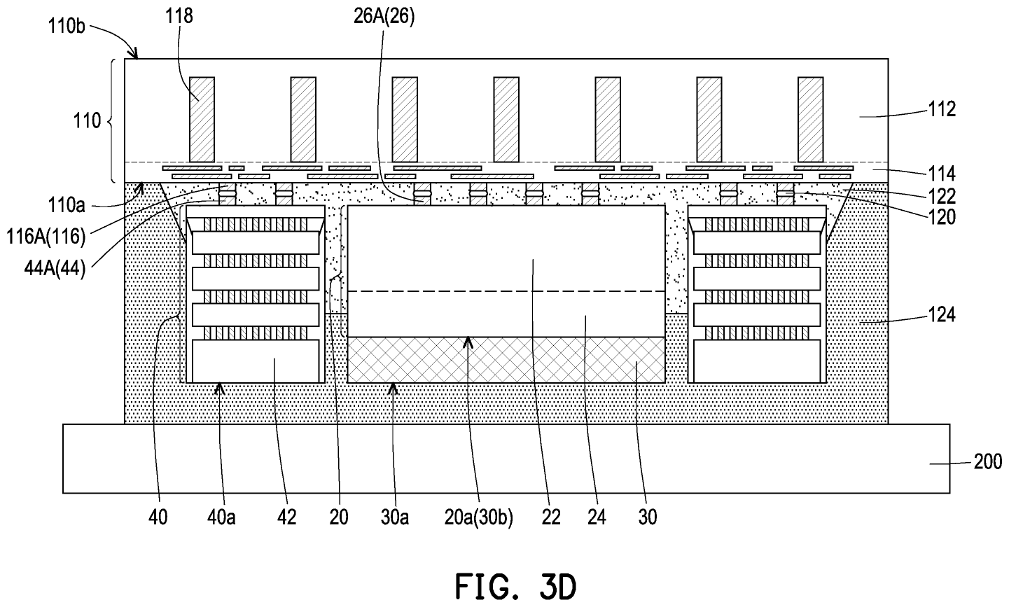

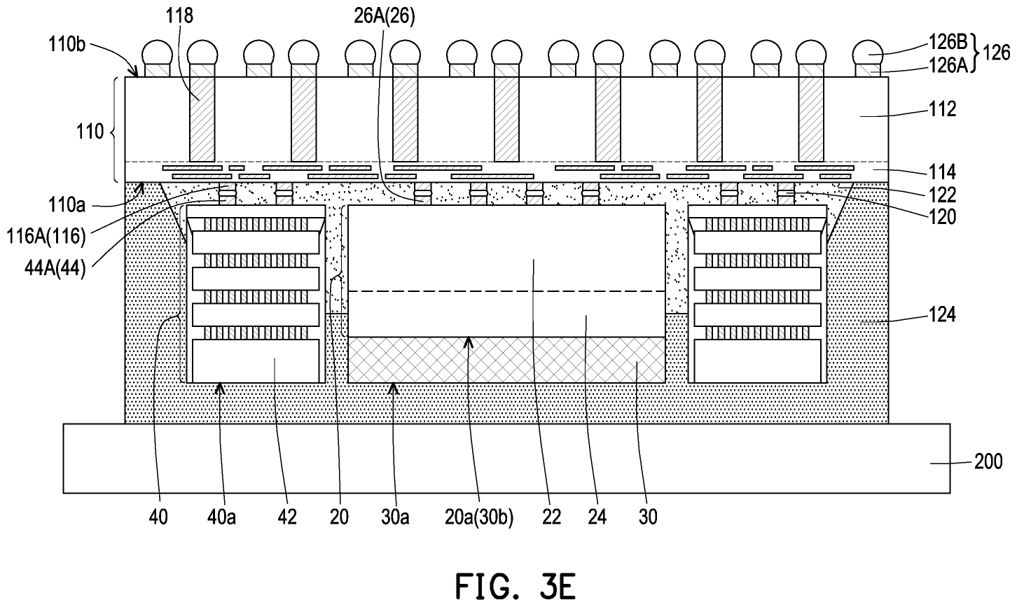

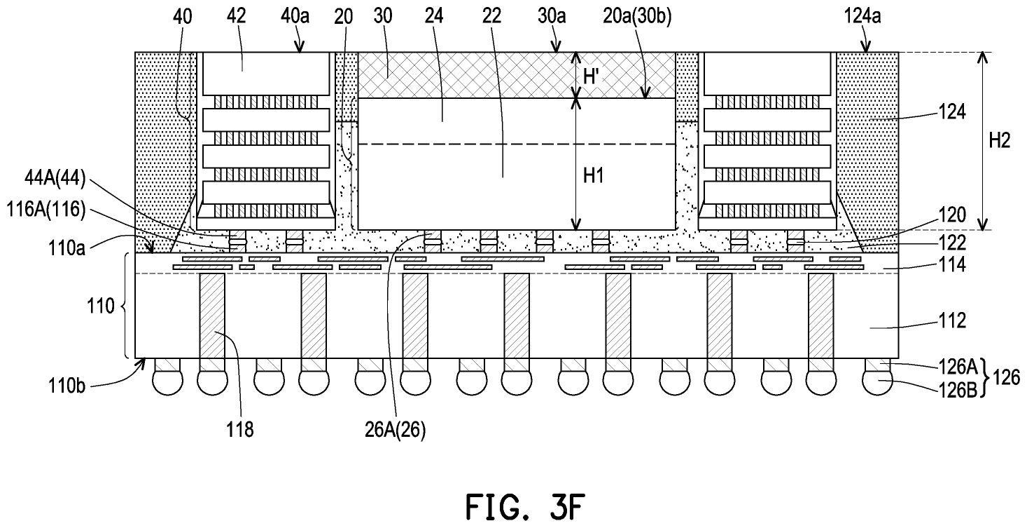

A thermal conductivity of the conductive paste 30 is larger than a thermal conductivity of the semiconductor substrate 22 of the integrated circuit die 20, adhesive layer such as thermal conductive die-attach-film (DAF) and/or molding compound. The conductive paste 30 may be a high k material having a thermal conductivity larger than 30 W/mK, for example, in a range of about 40 W/mK to 100 W/mK. The conductive paste 30 may be a silver paste such as silver paste including silver nanoparticles (e.g., thermal conductivity larger than 100 W/mK), silver sheets (e.g., thermal conductivity in a range of 10-50 W/mK) and/or silver powder (e.g., thermal conductivity in a range of 5-20 W/mK), a copper paste, a graphite paste, the like, or combinations thereof. In some embodiments, the formed conductive paste 30 has a size substantially the same as the first surface 10a of the wafer 10. For example, a covering range of the conductive paste on the first surface 10a of the wafer 10 is in a range of about 97.5% to 99.3%. A height (e.g., thickness) H′ of the conductive paste 30 is substantially equal to a height difference between the integrated circuit die 20 and the integrated circuit die to be packaged with the integrated circuit die 20 (e.g., a height difference between a height H1 of the integrated circuit die 20 and a height H2 of the integrated circuit die 40 in FIG. 3A). The thickness of the conductive paste 30 may be in a range of about 50 um to about 200 um. The conductive paste 30 is in direct contact with the first surface 10a (e.g., the outermost surface) of the wafer 10, for example.

Referring to FIG. 1C, after the conductive paste 30 is formed, a thinning process may be performed onto the second surface 10b of the wafer 10, so as to reduce the thickness of the wafer 10. In some embodiments, the thinning process is performed for total thickness variation (TTV) control. The thinning process may be a grinding process, a CMP, an etch-back, combinations thereof, or the like. In alternative embodiments, the grinding process is omitted.

Then, a plurality of conductive connectors 26 are formed on and electrically connected to the interconnect structure 24 to provide an external electrical connection to the circuitry and devices. For example, the conductive connectors 26 are formed at the second surface 10b of the wafer 10. In some embodiments, the conductive connectors 26 are ball grid array (BGA) connectors, solder balls, metal pillars, controlled collapse chip connection (C4) bumps, micro bumps, electroless nickel-electroless palladium-immersion gold technique (ENEPIG) formed bumps, or the like.

The conductive connectors 26 may include underbump metallizations (UBMs) 26A and solder regions 26B over the UBMs 26A. The UBMs 26A may be conductive pillars, pads, or the like. In some embodiments, the UBMs 26A may be formed by forming a seed layer over the interconnect structure 24. The seed layer may be a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 26A. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, nickel, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 26A.

In some embodiments, the UBMs 26A includes three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the UBMs 26A. Any suitable materials or layers of material that may be used for the UBMs 26A are fully intended to be included within the scope of the current application.

The solder regions 26B may include a solder material and may be formed over the UBMs 26A by dipping, printing, plating, or the like. The solder material may include, for example, lead-based and lead-free solders, such as Pb—Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free solders may further include SnCu compounds as well, without the use of silver (Ag). Lead-free solders may also include tin and silver, Sn—Ag, without the use of copper. In some embodiments, a reflow process may be performed, giving the solder regions 26B a shape of a partial sphere in some embodiments. In alternative embodiments, the solder regions 26B may have other shapes, such as non-spherical shapes.

In some embodiments, the solder regions 26B are used to perform chip probe (CP) testing on the integrated circuit die 20. For example, the solder regions are solder balls, solder bumps, or the like, which are used to attach a chip probe to the conductive connectors 26. Chip probe testing may be performed on the integrated circuit die 20 to ascertain whether the integrated circuit die 20 is a known good die (KGD). Thus, only integrated circuit dies 20, which are KGDs, undergo subsequent processing and are packaged, and dies which fail the chip probe testing are not packaged. In some embodiments, after testing, the solder regions 26B are removed in subsequent processing steps.

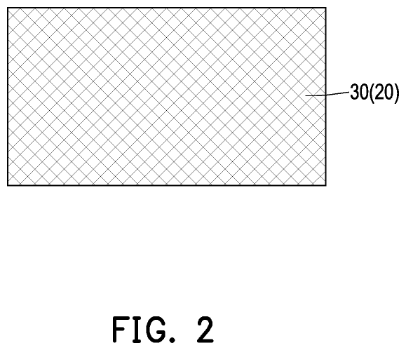

Referring to FIG. 1D, a singulation process is performed on the wafer-level structure of FIG. 1C by cutting along scribe line regions (e.g., dashed lines), e.g., around the die region 12. The singulation process may include sawing, etching, dicing, the like, or combinations thereof. For example, the singulation process includes sawing the substrate 22, the interconnect structure 24 and the conductive pates 30. The singulation process singulates the die region 12 from adjacent regions to form a singulated integrated circuit die 20 illustrated in FIG. 1E. The singulated integrated circuit die 20 is from the die region 12. Each integrated circuit die 20 has the conductive paste 30 on a first surface of the integrated circuit die 20. In some embodiments, the conductive connectors 26 are disposed at a second surface 20b opposite to the first surface 20a. In some embodiments, as shown in FIG. 1E and FIG. 2, the conductive paste 30 is continuously disposed on and in direct contact with the first surface 20a of the integrated circuit die and a sidewall (e.g., a periphery) of the conductive paste 30 is substantially flush with a sidewall (e.g., a periphery) of the integrated circuit die 20. For example, the conductive paste 30 substantially covers the first surface 20a of the integrated circuit die entirely. In some embodiments, a first surface 30a of the conductive paste 30 is exposed, and a second surface 30b opposite to the first surface 30a of the conductive paste 30 is in direct contact with the first surface 20a of the integrated circuit die 20.

FIG. 3A to FIG. 3F are schematic cross-sectional views of various stages in a method of forming a semiconductor device according to some embodiments.

Referring to FIG. 3A, an interposer 110 is obtained or formed. In some embodiments, the interposer 110 includes a substrate 112, an interconnect structure 114, and conductive connectors 116. In alternative embodiments, an interposer wafer including a plurality of package regions is obtained or formed. The interposer wafer includes an interposer in the package region, which will be singulated in subsequent processing to be included in a semiconductor device such as a semiconductor package.

The substrate 112 may be formed using similar materials and methods as the semiconductor substrate 22 described above with reference to FIG. 1A, and the description is not repeated herein. In some embodiments, the substrate 112 generally does not include active devices therein, although the interposers 110 may include passive devices formed in and/or on an active or a front-side surface (e.g., the surface facing upward in FIG. 3A) of the substrate 112. In alternative embodiments, active devices (e.g., transistors, diodes, etc.), capacitors, resistors, the like, or combinations thereof, are formed in and/or on the front-side surface of the substrate 112.

The interconnect structure 114 is formed over the front-side surface of the substrate 112, and is used to electrically connect the devices (if any) of the substrate 112. The interconnect structure 114 may include one or more dielectric layer(s) and respective metallization layer(s) in the dielectric layer(s). The interconnect structure 114 may be formed using similar materials and methods as the interconnect structure 24 described above with reference to FIG. 1A, and the description is not repeated herein. In some embodiments, the conductive connectors 116 are formed at a first surface 110a (e.g., front-side) of the interposer 110 as described above with reference to FIG. 1C, and the description is not repeated herein. For example, the conductive connectors 116 include UBMs 116A and solder regions 116B over the UBMs 116A.

Conductive vias 118 may extend into the interconnect structure 114 and/or the substrate 112. The conductive vias 118 are electrically connected to metallization layer(s) of the interconnect structure 114. The conductive vias 118 are also sometimes referred to as through substrate vias (TSVs). As an example to form the conductive vias 118, recesses can be formed in the interconnect structure 114 and/or the substrate 112 by, for example, etching, milling, laser techniques, the like, or combinations thereof. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, the like, or combinations thereof. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, the like, or combinations thereof. Examples of conductive materials are copper, tungsten, aluminum, silver, gold, the like, or combinations thereof. Excess conductive material and barrier layer is removed from a surface of the interconnect structure 114 or the substrate 112 by, for example, a CMP. Remaining portions of the barrier layer and conductive material form the conductive vias 118.

Referring to FIG. 3B, the integrated circuit die 20 and integrated circuit dies 40 are attached to the interposer 110. In some embodiments, a total height (e.g., H1 plus H′) of the integrated circuit die 20 and the conductive paste 30 thereon is substantially equal to a height (e.g., about 0.7 mm to 1.1 mm) H2 of the integrated circuit die 40. In other words, the conductive paste 30 may compensate the height difference between the integrated circuit die 20 and the integrated circuit dies 40 to be packaged. Thus, the surface 30a (e.g., top surface) of the conductive paste 30 on the integrated circuit die 20 may be substantially coplanar with surface 40a (e.g., top surfaces) of the integrated circuit dies 40, which is suitable for subsequent processing. In some embodiments, a single integrated circuit die 20 and two integrated circuit dies 40 are bonded to the interposer 110. In alternative embodiments in which the interposer wafer is provided, each package region of the interposer wafer includes a single integrated circuit die 20 and two integrated circuit dies 40. The integrated circuit die 20 is the integrated circuit die 20 of FIG. 1D, which may generate heat more than the integrated circuit die 40. Although a single integrated circuit die 20 is shown in the cross-sectional view in FIG. 3B, there may be a plurality of integrated circuit dies 20 on the interposer 110. The integrated circuit die 40 may be a stacked device that includes multiple semiconductor substrates 42. For example, the integrated circuit die 40 may be a memory device that includes multiple memory dies such as a hybrid memory cube (HMC) device, a high bandwidth memory (HBM) device, or the like. In such embodiments, the integrated circuit die 40 includes multiple semiconductor substrates 42 interconnected by through-substrate vias (TSVs) such as through-silicon vias (not shown). Each of the semiconductor substrates 42 may (or may not) have a separate interconnect structure. In some embodiments, the integrated circuit die 40 has conductive connectors 44 on the outermost surface. The conductive connectors 44 may be formed using similar materials and methods as the conductive connectors 26 described above with reference to FIG. 1C, and the description is not repeated herein. For example, the conductive connectors 44 include UBMs 44A and solder regions (e.g., portions of solder joints 120) over the UBMs 44A.

In some embodiments, the integrated circuit dies 20 and 40 are attached to the interconnect structure 114 of the interposer 110 using the conductive connectors 26, 44 and 116. The integrated circuit dies 20 and 40 may be placed on the interconnect structure 114 using, e.g., a pick-and-place tool. After placing the integrated circuit dies 20 and 40 on the interconnect structure 114, the solder regions 26B and 44B of the conductive connectors 26 and 44 are in physical contact with respective solder regions 116B of respective conductive connectors 116. After placing the integrated circuit dies 20 and 40 on the interconnect structure 114, a reflow process may be performed on the conductive connectors 26, 44 and 116. The reflow process may melt and merges the solder regions 26B, 44B and 116B into solder joints 120. The solder joints 120 electrically and mechanically couple the integrated circuit dies 20 and 40 to the interconnect structure 114, for example.

Referring to FIG. 3C, an underfill 122 may be formed around the solder joints 120, and in a gap between the interconnect structure 114 and the integrated circuit dies 20 and 40. The underfill 122 may reduce stress and protect the solder joints 120. The underfill 122 may be formed of an underfill material such as a molding compound, epoxy, or the like. The underfill 122 may be formed by a capillary flow process after the integrated circuit dies 20 and 40 are attached to the interconnect structure 114, or may be formed by a suitable deposition method before the integrated circuit dies 20 and 40 are attached to the interconnect structure 114. The underfill 122 may be applied in liquid or semi-liquid form and then subsequently cured. In some embodiments, the underfill 122 partially or fully fills gaps between adjacent ones of the integrated circuit dies 20 and 40, such that the underfill 122 extends along sidewalls of the integrated circuit dies 20 and 40.

Then, an encapsulant 124 is formed on and around the integrated circuit dies 20 and 40. After formation, the encapsulant 124 encapsulates the integrated circuit dies 20 and 40 and the underfill 122. The encapsulant 124 covers the conductive paste 30 on the integrated circuit die 20 and fills the gaps between the conductive paste 30 and the integrated circuit die 40. The encapsulant 124 may be a molding compound, epoxy, or the like. The encapsulant 124 may not include fillers therein. The encapsulant 124 may be applied by compression molding, transfer molding, or the like, and is formed over the interposer 110 such that the integrated circuit dies 20 and 40 are buried or covered. The encapsulant 124 may be applied in liquid or semi-liquid form and then subsequently cured.

Referring to FIG. 3D, the interposer 110 is flipped over and is attached to a carrier wafer 200, and portions of the encapsulant 124 are removed. The carrier wafer 200 is used as a platform or a support for a packaging process described below. In some embodiments, the carrier wafer 200 includes a semiconductor material (such as silicon, or the like), a dielectric material (such as glass, a ceramic material, quartz, or the like), the like, or combinations thereof. Portions of the encapsulant 124 may be removed by a trimming process with a pressure anneal. As a result of the partial removal of the encapsulant 124, the outer sidewalls of the interposer 110 and the encapsulant 124 are laterally coterminous (within process variations).

Referring to FIG. 3E, the substrate 112 is thinned to expose the conductive vias 118. Exposure of the conductive vias 118 may be accomplished by a thinning process, such as a grinding process, a CMP, an etch-back, combinations thereof, or the like. In some embodiments (not separately illustrated), the thinning process for exposing the conductive vias 118 includes a CMP, and the conductive vias 118 protrude at a second surface 110b (e.g., backside) of the interposer 110 as a result of dishing that occurs during the CMP. In such embodiments, an insulating layer (not separately illustrated) is optionally be formed on the backside of the substrate 112, surrounding the protruding portions of the conductive vias 118. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. After the substrate 112 is thinned, the exposed surfaces of the conductive vias 118 and the insulating layer (if present) or the substrate 112 are coplanar (within process variations), such that they are level with one another, and are exposed at the backside of the interposer 110. Subsequently, conductive connectors 126 are formed on the second surface 110b (e.g., the backside) of the interposer 110 as the conductive connectors 26 described above with reference to FIG. 1C, and the description is not repeated herein. In the illustrated embodiment, the conductive connectors 126 comprise UBMs 126A, and solder regions 126B over the UBMs 126A. The UBMs 126A and the solder regions 126B may be formed using similar material and methods as the UBMs 26A and the solder regions 26B, respectively, described above with reference to FIG. 1C, and the description is not repeated herein.

Referring to FIG. 3F, the structure of FIG. 3E is mounted onto a frame (not specifically illustrated), and de-bonded from the carrier wafer 200. The package component including the integrated circuit dies 20 and 40 and the encapsulant 124 is de-bonded from the carrier wafer 200.

After de-bonded from the carrier wafer 200, the encapsulant 124 may be thinned to expose the conductive paste 30 on the integrated circuit die 20 and the integrated circuit dies 40. The thinning process may be a grinding process, a CMP, an etch-back, combinations thereof, or the like. After the thinning process, the surfaces (e.g., top surfaces) 30a, 40a, 124a of the conductive paste 30 on the integrated circuit die 20, the integrated circuit dies 40, and the encapsulant 124 are substantially coplanar (within process variations), such that they are level with one another. For example, the surface 30a (e.g., top surface) of the conductive paste 30 is substantially coplanar with the first surface 40a (e.g., top surface) of the semiconductor substrate 42 of the integrated circuit die 40. The thinning is performed until a desired amount of the encapsulant 124, the conductive paste 30 and/or the integrated circuit dies 40 has been removed. The encapsulant 124 may be in direct contact with the sidewalls (e.g., peripheries) of the conductive paste 30 and the integrated circuit die 20. In some embodiments, the conductive paste 30 compensates height difference between the integrated circuit die 20 and other dies to be packaged. In addition, since the thermal conductivity of the conductive paste 30 may be larger than a thermal conductivity of the semiconductor substrate 22 of the integrated circuit die 20 and/or the encapsulant 124, the conductive paste 30 may provide a good heat dissipation for the integrated circuit die 20.

In alternative embodiments in which the interposer wafer is provided, removal of partial encapsulant 124 as illustrated in FIG. 3D is omitted, and a singulation process is performed after forming the conductive connectors 126. The singulation process is performed on the package component by cutting along scribe line regions, e.g., around the package region. The singulation process may include sawing, etching, dicing, the like, or combinations thereof. In such embodiments, the singulation process includes sawing the encapsulant 124, the interconnect structure 114 and the substrate 112. The singulation process singulates the package region from adjacent package regions to form a singulated semiconductor device as illustrated in FIG. 3F. The singulated semiconductor device is from the package region. The singulation process forms interposers 110 from the singulated portions of the interposer wafer.

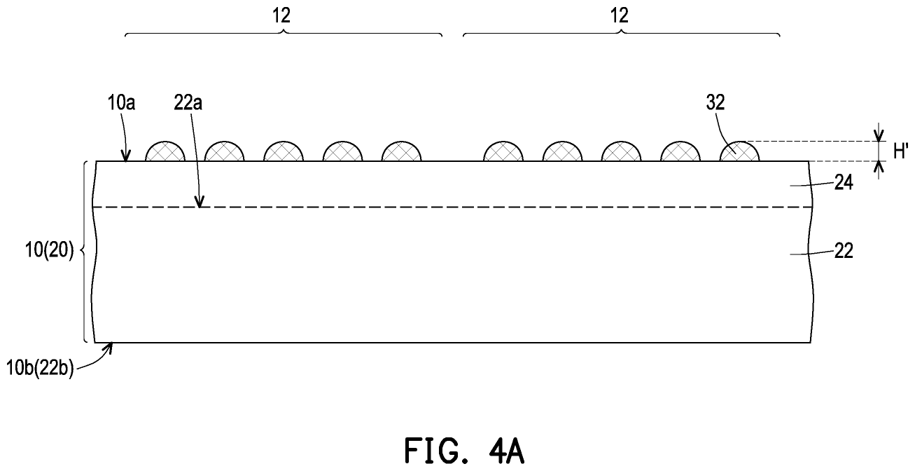

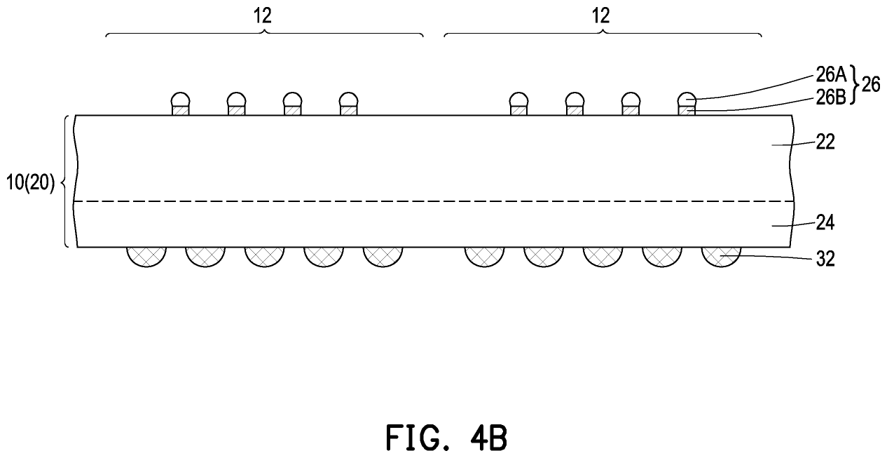

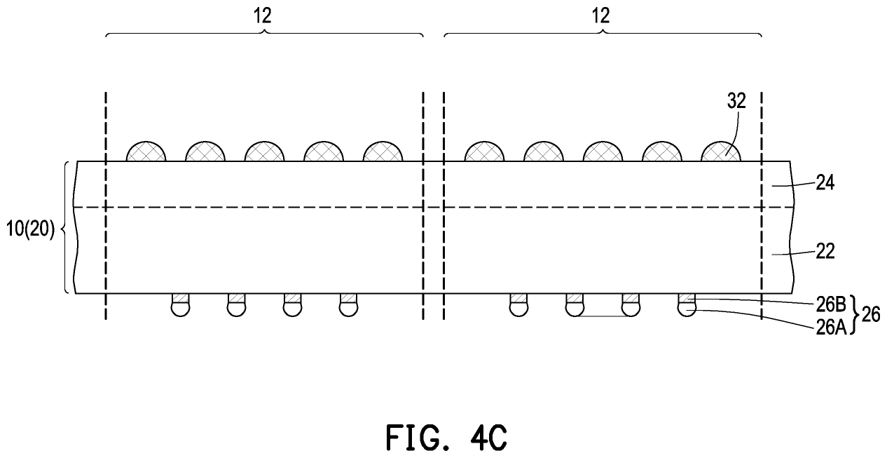

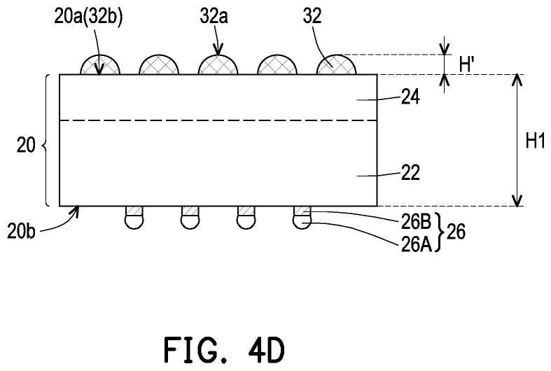

FIG. 4A to FIG. 4D are schematic cross-sectional views of various stages in a method of forming a semiconductor device according to some embodiments.

Referring to FIG. 4A, a plurality of heat dissipation patterns 32 are formed on the first surface 10a of the wafer 10. The heat dissipation patterns 32 are separated from each other. A thermal conductivity of the heat dissipation pattern 32 is larger than a thermal conductivity of the semiconductor substrate 22 of the integrated circuit die 20, adhesive layer such as thermal conductive die-attach-film (DAF) and/or molding compound. The heat dissipation patterns 32 may include a high k material having a thermal conductivity larger than 30 W/mK, for example, in a range of about 40 W/mK to 100 W/mK. The high k material may be a low thermal resistant material with feasible process capability.

The heat dissipation patterns 32 are formed by a 3D printing process, a dispensing process, a placement process, the like, combinations thereof, or any other suitable process. In some embodiments, conductive powder is printed onto the first surface 10a of the wafer 10 by 3D printing process with laser, so as to form the heat dissipation patterns 32. The conductive powder may be a high k material having a thermal conductivity larger than 5 W/mK, for example, in a range of about 5 to 20 W/mK. The conductive powder may be silver powder (e.g., thermal conductivity in a range of 5-20 W/mK). In such embodiments, a sintering process is not needed. In alternative embodiments, the heat dissipation patterns 32 are formed by dispensing conductive paste at different sites of the first surface 10a of the wafer 10 with a dispensing device. The conductive paste may have a thermal conductivity larger than 30 W/mK, for example, in a range of about 40 W/mK to 100 W/mK. The conductive paste may be a silver paste such as nanosilver paste, a copper paste, a graphite paste, the like, or combinations thereof. In alternative embodiments, the heat dissipation patterns 32 are respectively formed by placing and/or adhering to the first surface 10a of the wafer 10. In such embodiments, the heat dissipation pattern 32 is in a form of block or film, and a material of the heat dissipation pattern 32 includes a high k material having a thermal conductivity larger than 30 W/mK, for example, in a range of about 40 W/mK to 100 W/mK. For example, the heat dissipation patterns 32 include metal such as silver or copper or other suitable material. In some embodiments, the heat dissipation patterns 32 are formed by forming a high k material on the first surface 10a of the wafer 10 and then patterning the high k material by using a lithography process. The high k material may have a thermal conductivity larger than 30 W/mK, for example, in a range of about 40 W/mK to 100 W/mK. The high k material may include metal such as silver or copper. In some embodiments, the heat dissipation patterns 32 are wires. In some embodiments, after the heat dissipation patterns 32 are formed onto the first surface 10a of the wafer 10, a sintering process is performed on the conductive paste, at a sintering temperature of about 180° C. to about 250° C. for about 30 minutes to 240 minutes. The heat dissipation patterns 32 are in direct contact with the first surface 10a (e.g., the outermost surface) of the wafer for example.

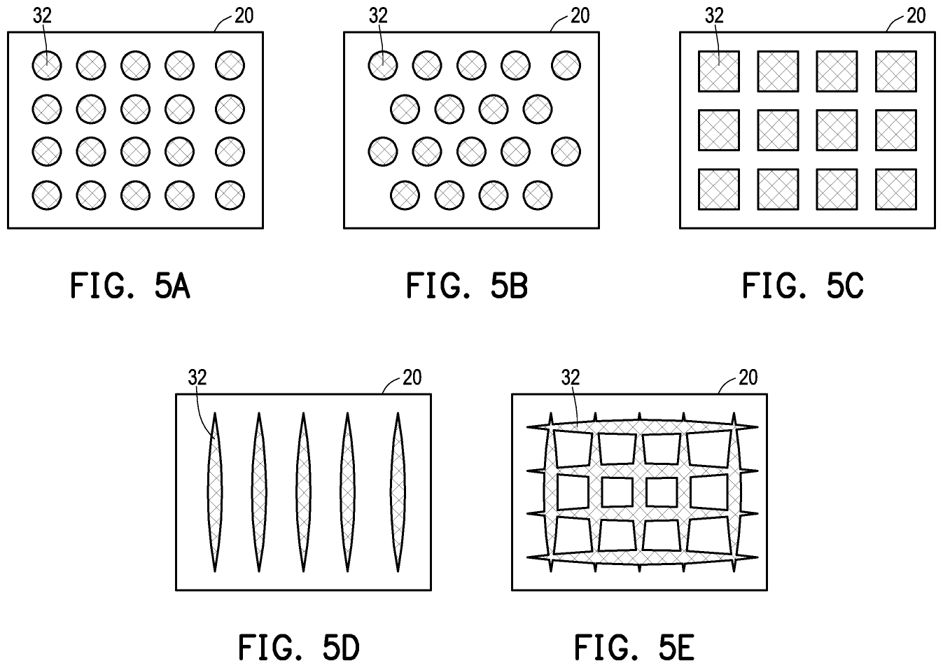

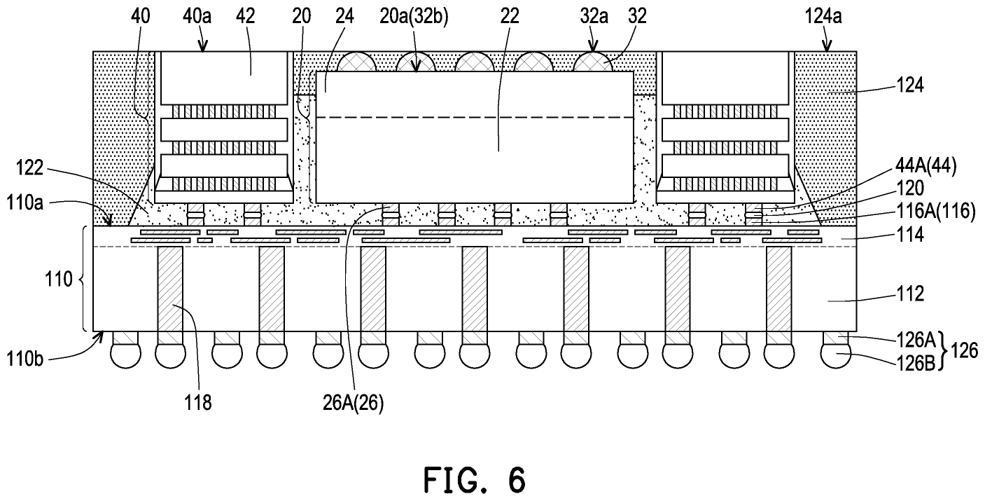

The heat dissipation patterns 32 may be shaped as a drop or a cone. However, the disclosure is not limited thereto. In some embodiments, from a top view, the heat dissipation patterns 32 are each shaped in circle or spot (as shown in FIG. 5A or FIG. square or rectangular (as shown in FIG. 5C), bar, line or fusiform (as shown in FIG. a wedge, the like, or combinations thereof. In some embodiments, the heat dissipation patterns 32 are separated from each other. However, the disclosure is not limited thereto. In some embodiments, some heat dissipation patterns 32 are physically connected while others are separated from each other. In some embodiments, as shown in FIG. 5E, the heat dissipation patterns 32 are physically connected to form a net. In some embodiments, the heat dissipation patterns 32 are arranged in an array (as shown in FIG. 5A) or in a zigzag arrangement (as shown in FIG. 5B). The heat dissipation pattern 32 may have a diameter (e.g., a bottom width) in a range of 0.4 mm to 1.5 mm. A height H′ of the heat dissipation pattern 32 is substantially equal to a height difference between the integrated circuit die 20 and the integrated circuit die to be packaged with the integrated circuit die 20 (e.g., a height difference between the integrated circuit die and the integrated circuit die 40 in FIG. 6). The height of the heat dissipation pattern 32 may be in a range of about 0.15 mm to about 0.4 mm such as about 50 um to about 200 um. The width of the heat dissipation patterns 32 may be in a range of 0.2 mm to 2.0 mm. The separations between the heat dissipation patterns 32 may be the same or different. In some embodiments, the heat dissipation patterns 32 provide a large surface area for dissipation since the heat dissipation patterns 32 is each a three dimensional structure. In addition, a total usage of the material of the heat dissipation patterns 32 may be reduced due to the separation therebetween.

Referring to FIG. 4B, after the heat dissipation pattern 32 are formed, a thinning process may be performed onto the second surface 10b of the wafer 10, so as to reduce the thickness of the wafer 10. In some embodiments, the thinning process is performed for total thickness variation (TTV) control. The thinning process may be a grinding process, a CMP, an etch-back, combinations thereof, or the like. In alternative embodiments, the grinding process is omitted. Then, a plurality of electrical connectors 26 are formed on and electrically connected to the connectors 24 to provide an external electrical connection to the circuitry and devices. The step is similar to the step described above with reference to FIG. 1C, and the description is not repeated herein.

Referring to FIG. 4C, a singulation process is performed on the wafer-level structure of FIG. 4B by cutting along scribe line regions (e.g., dashed lines), e.g., around the die region 12. A singulated integrated circuit die 20 illustrated in FIG. 4D is formed. The step is similar to the step described above with reference to FIG. 1D, and the description is not repeated herein. In some embodiments, each integrated circuit die 20 has a plurality of heat dissipation patterns 32 on the first surface 20a (i.e., the outermost surface) of the integrated circuit die 20.

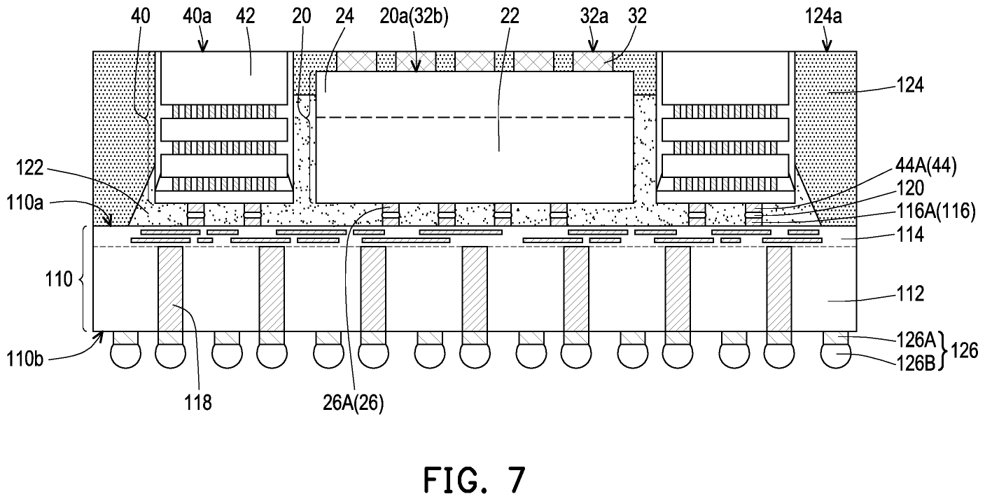

The formed integrated circuit die 20 may be integrated with the integrated circuit die(s) 40 to form a semiconductor device as shown in FIG. 6. The semiconductor device may be formed using similar materials and methods as the semiconductor device described above with reference to FIG. 3A to FIG. 3F, and the description is not repeated herein. In some embodiments, a total height (e.g., H1 plus H′) of the integrated circuit die 20 and the heat dissipation patterns 32 thereon is substantially equal to a height H2 of the integrated circuit die 40. In other words, the heat dissipation patterns 32 may compensate the height difference between the integrated circuit die 20 and the integrated circuit dies 40 to be packaged. Thus, surfaces 32a (e.g., top surfaces) of the heat dissipation patterns 32 on the integrated circuit die 20 may be substantially coplanar with the surface 40a (e.g., top surfaces) of the integrated circuit dies 40. In such embodiments, after the encapsulant 124 is formed to cover the surfaces 32a, 40a of the heat dissipation patterns 32 and the integrated circuit dies 40, the encapsulant 124 is thinned to expose the surfaces 32a, 40a of the heat dissipation patterns 32 and the integrated circuit dies 40. The encapsulant 124 may be filled between the heat dissipation patterns 32 and between the heat dissipation pattern 32 and the integrated circuit die 40. The encapsulant 124 is in direct contact with sidewalls of the heat dissipation patterns 32, for example. The surfaces 32a, 40a of the heat dissipation patterns 32 and the integrated circuit dies 40 are substantially coplanar with a surface (e.g., top surface) 124a of the encapsulant 124. In some embodiments, as shown in FIG. 7, the heat dissipation patterns 32 have other suitable cross-sectional shape such as a rectangle, and the heat dissipation patterns 32 have larger exposed surfaces (e.g., top surfaces). In some embodiments, the surfaces 32a of the heat dissipation patterns 32 are substantially coplanar with the surface (e.g., top surface) 40a of the integrated circuit dies 40 and a surface (e.g., top surface) 124a of the encapsulant 124. In some embodiments, the encapsulant 124 between the heat dissipation patterns 32 as shown in FIG. 6 and FIG. 7 is referred to as an encapsulating pattern. For example, the encapsulating patterns are disposed between the heat dissipation patterns 32 and surfaces of the patterns are substantially coplanar with the surfaces 32a of the heat dissipation patterns 32.

In some embodiments, the thermal conductivity of the heat dissipation patterns 32 is larger than a thermal conductivity of the semiconductor substrate 22 of the integrated circuit die 20 and/or the encapsulant 124, and thus the heat dissipation patterns 32 may provide a good heat dissipation for the integrated circuit die 20. In alternative embodiments, the encapsulant 124 further includes a high k molding compound having a thermal conductivity larger than 30 W/mK, for example, in a range of about 40 W/mK to 100 W/mK. Thus, the heat dissipation patterns 32 and the encapsulant 124 on the surface 20a (e.g., the outermost surface) of the integrated circuit die 20 may collectively provide more thermal capacity. In such embodiments, the encapsulant 124 between the heat dissipation patterns 32 may be also referred to as a heat dissipation pattern.

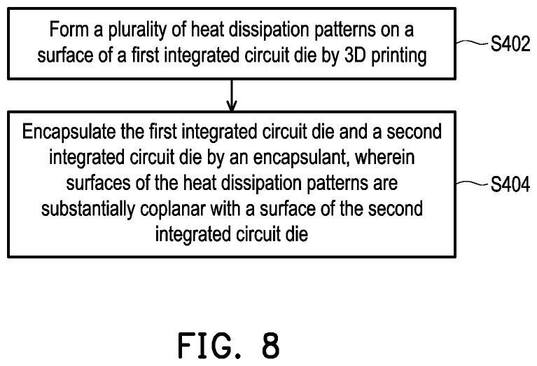

FIG. 8 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 5402, a plurality of heat dissipation patterns are formed on a surface of a first integrated circuit die by 3D printing. FIG. 4A to FIG. 4D and FIG. 5A to FIG. 5E illustrate views corresponding to some embodiments of act 5402.

At act 5404, the first integrated circuit die and a second integrated circuit die are encapsulated by an encapsulant, wherein surfaces of the heat dissipation patterns are substantially coplanar with a surface of the second integrated circuit die. FIG. 6 and FIG. 7 illustrate views corresponding to some embodiments of act 5404.

According to some embodiments, a semiconductor device includes a first integrated circuit die and a second integrated circuit die. The first integrated circuit die includes a conductive paste on a first surface of the first integrated circuit die, wherein the conductive paste is in direct contact with the first surface of the first integrated circuit die. The second integrated circuit die is disposed aside the first integrated circuit die, wherein a surface of the conductive paste is substantially coplanar with a surface of the second integrated circuit die.

According to some embodiments, a semiconductor device includes a first integrated circuit die, a plurality of heat dissipation patterns and an encapsulant. The heat dissipation patterns are disposed on an outermost surface of the first integrated circuit die, wherein the heat dissipation patterns are in direct contact with the outermost surface of the first integrated circuit die. The encapsulant encapsulates the first integrated circuit die, wherein the encapsulant is disposed between the heat dissipation patterns.

According to some embodiments, a method of forming a semiconductor device includes following steps. A plurality of heat dissipation patterns are formed on a surface of a first integrated circuit die by 3D printing. The first integrated circuit die and a second integrated circuit die are encapsulated by an encapsulant, wherein surfaces of the heat dissipation patterns are substantially coplanar with a surface of the second integrated circuit die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first integrated circuit die, comprising a conductive paste on a first surface of the first integrated circuit die, wherein the conductive paste is in direct contact with the first surface of the first integrated circuit die; and
a second integrated circuit die aside the first integrated circuit die, wherein a surface of the conductive paste is substantially coplanar with a surface of the second integrated circuit die.

2. The semiconductor device of claim 1, wherein the conductive paste includes a silver paste, a copper paste, a graphite paste or combinations thereof.

3. The semiconductor device of claim 1, wherein a thermal conductivity of the conductive paste is larger than 30 W/mk.

4. The semiconductor device of claim 1, wherein a periphery of the conductive paste has a size substantially the same as a periphery of the first surface of the first integrated circuit die.

5. The semiconductor device of claim 1, further comprising an encapsulant encapsulating the first integrated circuit die and the second integrated circuit die, wherein the encapsulant is in direct contact with the first integrated circuit die and the conductive paste.

6. The semiconductor device of claim 1, further comprising an interposer, wherein the first integrated circuit die and the second integrated circuit die are attached to the interposer.

7. The semiconductor device of claim 6, further comprising an underfill between the interposer and the first integrated circuit die and between the interposer and the second integrated circuit die, wherein the first integrated circuit die is disposed between the conductive paste and the interposer.

8. A semiconductor device, comprising:
a first integrated circuit die;
a plurality of heat dissipation patterns on an outermost surface of the first integrated circuit die, wherein the heat dissipation patterns are in direct contact with the outermost surface of the first integrated circuit die; and
an encapsulant, encapsulating the first integrated circuit die, wherein the encapsulant is disposed between the heat dissipation patterns.

9. The semiconductor device of claim 8, wherein the heat dissipation patterns each include a conductive paste, a conductive pattern or combinations thereof.

10. The semiconductor device of claim 8, wherein the heat dissipation patterns each include silver powder.

11. The semiconductor device of claim 8, wherein the heat dissipation patterns are arranged in an array.

12. The semiconductor device of claim 8, wherein the encapsulant further encapsulates a second integrated circuit die, and surfaces of the heat dissipation patterns are substantially coplanar with the second integrated circuit die.

13. The semiconductor device of claim 8, wherein a surface of the encapsulant is substantially coplanar with surfaces of the heat dissipation patterns.

14. The semiconductor device of claim 8, wherein a top view of a shape of the heat dissipation patterns includes circle, rectangular, fusiform or combinations thereof.

15. The semiconductor device of claim 8, wherein the heat dissipation patterns are connected to form a net.

16. A method of forming a semiconductor device, comprising:
forming a plurality of heat dissipation patterns on a surface of a first integrated circuit die by 3D printing; and
encapsulating the first integrated circuit die and a second integrated circuit die by an encapsulant, wherein surfaces of the heat dissipation patterns are substantially coplanar with a surface of the second integrated circuit die.

17. The method of claim 16, wherein the heat dissipation patterns are formed by 3D printing conductive powder onto the surface of the first integrated circuit die with laser.

18. The method of claim 17, wherein the conductive powder includes silver powder.

19. The method of claim 16, wherein a surface of the encapsulant is substantially coplanar with the surfaces of the heat dissipation patterns and the second integrated circuit die.

20. The method of claim 16, wherein the encapsulant is disposed between the heat dissipation patterns.
